(19) United States
(12) Patent Application Publication
(10) Pub. No.: US 2004/0075468 A1
(43) Pub. Date: Apr. 22, 2004

(54) Digital signal driver circuit

(76) Inventor: Bryan Haskin, Ft. Collins, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/271,818

(22) Filed: Oct. 16, 2002

(51) Int. Cl. H03K 19/094

(52) U.S. Cl. 326/83

(57) ABSTRACT

An enhanced digital signal driver circuit that allows the driving of digital signals with a larger voltage swing than that which is typically allowed by the associated IC technology is provided. The driver circuit employs PFETs and NFETs that clip the voltage present across both the drain-to-source and gate-to-source junctions of a driving PFET and a driving NFET of the driver circuit. The clipping PFETs and NFETs ensure that the drain-to-source and gate-to-source voltages of all of the FETs of the driver circuit are within the voltage design limits of the associated IC technology when the imposed power supply and digital signal voltages are substantially higher than those for which the associated IC technology was designed.

### BACKGROUND OF THE INVENTION

CMOS-based (complementary metal-oxide-semiconductor) digital logic IC (integrated circuit) technologies have been devised over the last several years which operate at progressively lower power supply voltages with each passing design generation. Lower supply voltages dictate lower voltage swings for the associated digital signals, which typically traverse between ground and the power supply voltage. The benefits of using lower supply voltages are lower power consumption and faster signal switching times. CMOS logic IC power supply voltages currently available include, for example, 3.3 volts (V), 2.5 V, 1.8 V, and 1.5 V. Due to the multitude of IC technologies available, a mix of these technologies may be used in any particular electronic product.

One consequence of this mixing of technologies is that a digital signal with a relatively high voltage swing, such as a signal switching between 0 and 3.3 V, may have to be driven either off-chip or on-chip via input/output (I/O) pads using IC technology designed for lower voltages swings, such as from 0 to 2.5 V. Typically, for economic considerations, a single IC technology is utilized for the I/O pads of an IC. As lower voltage IC technology, such as 2.5 V circuitry, generally provides higher performance than that associated with higher voltages, such as 3.3 V, lower voltage IC technology is normally selected for all I/O pads of an IC. Therefore, the desirable solution in most cases is to employ low-voltage IC technology for all I/O signals, no matter what voltage range they traverse.

FIG. 1 shows a standard digital signal driver circuit 1, consisting of a pair of complementary MOS FETs (Field Effect Transistors) structured as a CMOS inverter. A PFET (p-channel FET) P₁ and an NFET (n-channel FET) N₁ are connected in series between a power supply voltage V_{DD} and a ground reference. The gate terminals of P₁ and N₁ are connected together and driven by an input signal V_{IN}. The source terminal of P₁ and the drain terminal of N₁ are connected together to drive an output signal V_{OUT}.

FIG. 2 graphically shows the operation of the standard driver circuit 1. As V_{IN} rises from LOW logic state at about zero volts up to a HIGH logic state of essentially V_{DD} volts, P₁ turns OFF and N₁ turns ON, thereby driving V_{OUT} from about V_{DD} volts down to near zero volts. Oppositely, when V_{IN} then returns from its HIGH state down to its low voltage level, P₁ returns to its ON state, N₁ shuts off, thereby driving V_{OUT} up close to V_{DD} volts.

Therefore, each of the FETs P₁ and N₁ must be able to handle drain-to-source voltages of approximately V_{DD} volts. Unfortunately, in the case of a V_{DD} power supply voltage of approximately 3.3 V, IC technology that is designed to support a V_{DD} of 2.5 V cannot reliably handle such significantly higher power supply and digital signal voltages. For example, assume the standard driver circuit 1 was manufactured using 2.5 V technology. If a V_{DD} of 3.3 V is employed to support input is and output signals switching between zero and 3.3 V, P₁ and N₁, each will periodically have about 3.3 V across their drain-to-source junctions. As P₁ and N₁ are designed for 2.5 V operation, the overvoltage across each FET is likely to cause their eventual breakdown, resulting in the ultimate failure of the standard driver circuit 1. Additionally, the extensive voltage swing in the input signal V_{IN} periodically places 3.3 V across the gate-to-source junctions of both P₁ and N₁, which also are only designed to handle 2.5 V. This gate-to-source overvoltage promotes breakdown of the FET gate oxide, causing even more permanent damage to the FETs involved.

Alternately, as displayed in FIG. 3, small linearizing resistors R_{P} and R_{N} may be connected in series with P₁ and N₁, respectively, resulting in a modified driver circuit 2. Although any current passing through the resistors R_{P} and R_{N} will cause a small portion of the high voltage power supply V_{DD} to appear across the resistors, the voltage across each of the FETs P₁ and N₁ is likely to still be too high to guarantee proper operation of the modified driver circuit 2.

From the foregoing, a need exists for a driver circuit that drives digital signals and utilizes a power supply voltage that both exhibit higher voltage levels than those for which the associated IC technology was designed. Such a driver circuit would operate under those high voltage conditions without suffering significant voltage breakdown or other reliability problems.

### SUMMARY OF THE INVENTION

Embodiments of the invention, to be discussed in detail below, utilize PFETs and NFETs that clip the voltage present across both the drain-to-source and gate-to-source junctions of a driving PFET and driving NFET of the driver circuit. The clipping PFETs and NFETs ensure that the drain-to-source and gate-to-source voltages of all of the FETs of the driver circuit are within the voltage design limits of the associated IC technology when the imposed power supply and digital signal voltages are substantially higher than those for which the associated IC technology was designed.

Other aspects and advantages of the invention will become apparent from the following detailed description, taken in conjunction with the accompanying drawings, illustrating by way of example the principles of the invention.

### BRIEF DESCRIPTION OF THE DRAWINGS

FIG. 1 is a schematic diagram of a standard digital signal driver circuit from the prior art.

FIG. 2 is an idealized voltage vs. time graph describing the operation of the standard digital signal driver circuit of FIG. 1.

FIG. 3 is a schematic diagram of a modified driver circuit from the prior art.

FIG. 4 is a schematic diagram of a digital signal driver circuit according to an embodiment of the invention.

FIG. 5A and FIG. 5B are schematic diagrams of two alternative active voltage dividers that generate bias voltages for the digital signal driver circuit of FIG. 4.

FIG. 6 is an idealized voltage vs. time graph describing the operation of the digital signal driver circuit of FIG. 4.

FIG. 7 is a schematic diagram of a second digital signal driver circuit according to an embodiment of the invention.

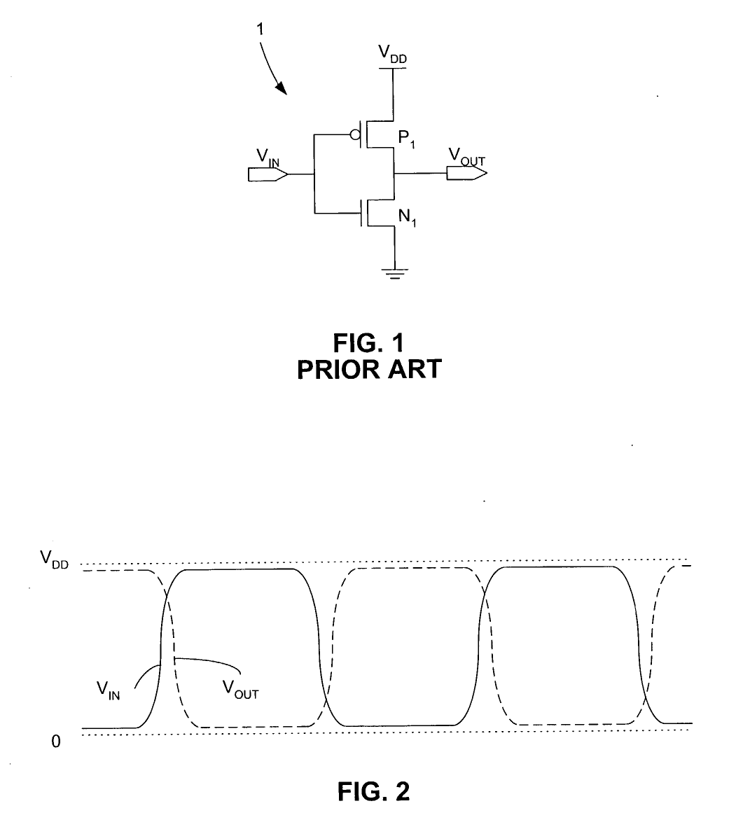

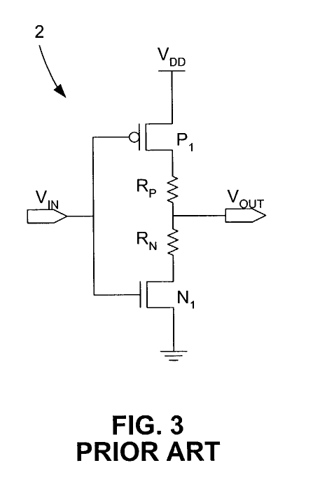

### DETAILED DESCRIPTION OF THE PREFERRED EMBODIMENTS

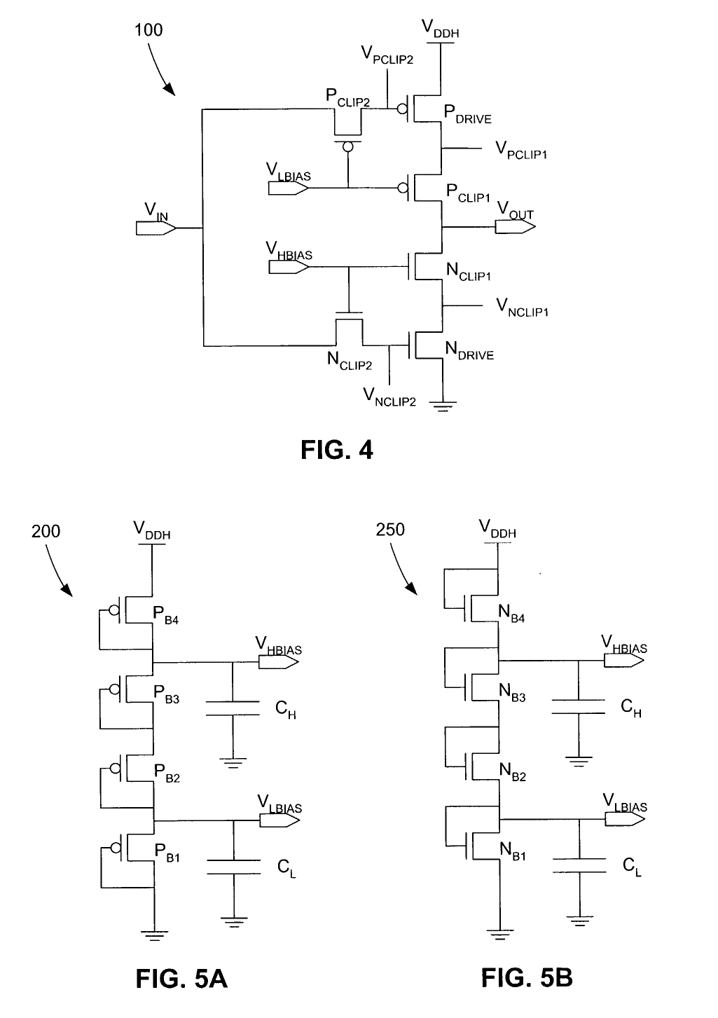

One embodiment of the invention, an enhanced digital signal driver circuit 100, is displayed in FIG. 4. A p-channel FET P_{DRIVE} and an n-channel FET N_{DRIVE} are employed to drive an output signal V_{OUT} to a logic HIGH or LOW, depending on the voltage level of an input signal V_{IN}. In the case of FIG. 4, a logic HIGH for either V_{IN} or V_{OUT} corresponds with a high voltage power supply V_{DDH}, and a logic LOW is essentially at a ground reference point. Assuming that the enhanced driver circuit 100 is implemented using technology suited for lower power supply voltages, the presence of voltage of the magnitude of V_{DDH} would cause reliability problems within the enhanced driver circuit 100 without the surrounding circuitry shown. For example, if V_{DDH} were approximately 3.3 V, and the circuit used to implement the enhanced driver circuit 100 were designed for 2.5 V operation, the presence of 3.3 V across the drain-to-source junction or the gate-source junction of either P_{DRIVE} or N_{DRIVE} would likely cause reliability problems, and possibly permanent damage, to those FETs, as described above in relation to the prior art standard driver circuits 1 and 2.

To alleviate this problem, the enhanced driver circuit 100 includes additional circuitry that “clips,” or reduces, the voltage imposed on the driving FETs P_{DRIVE} and N_{DRIVE}. With respect to P_{DRIVE}, a PFET P_{CLIP1} is positioned in series with P_{DRIVE} between the source of P_{DRIVE} and the output signal V_{OUT}. P_{CLIP1} clips the voltage across the drain-to-source junction of P_{DRIVE} by sharing part of the high voltage power supply level V_{DDH} that will exist across P_{DRIVE} and P_{CLIP1} whenever V_{OUT} is driven LOW, close to the ground voltage reference. With each of P_{DRIVE} and P_{CLIP1} sharing a portion of V_{DDH}, both of those two FETs will be operating within their voltage design limits, thus eliminating the reliability concerns associated with older driver circuits.

A second P_{FET}, P_{CLIP2}, addresses the problem of potentially excessive voltage across the gate-to-source junction of P_{DRIVE} by sharing that voltage with P_{DRIVE}. For example, with V_{IN} at a logic LOW level, V_{OUT} will be driven HIGH, thus causing both the source and drain of P_{DRIVE} to reside at or near V_{DDH} volts. If V_{IN} were to be asserted directly at the gate of P_{DRIVE}, the gate-to-source (and gate-to-drain) junction of P_{DRIVE} would have to handle the full magnitude of V_{DDH}, potentially causing gate oxide breakdown of P_{DRIVE}, as described above. However, with P_{CLIP2} residing between the input signal V_{IN} and the gate of P_{DRIVE}, the possibility for V_{DDH} volts to be impressed across the gate-to-source (or gate-to-drain) junction of P_{DRIVE} is eliminated due to P_{CLIP2} accepting part of that voltage.

Concerning the bottom portion of the enhanced driver circuit 100, as depicted in FIG. 4, the driving FET N_{DRIVE} is similarly protected by way of a pair of clipping NFETs, N_{CLIP1} and N_{CLIP2}. These clipping NFETs work in a fashion analogous to the clipping PFETs P_{CLIP1} and P_{CLIP2}, described above. The drain-to-source junction of N_{DRIVE} is protected by the use of N_{CLIP1} between the drain of N_{DRIVE} and the output signal V_{OUT} during those times when V_{OUT} is at a logic HIGH level as a result of V_{IN} being forced toward the ground reference voltage. Similarly, N_{CLIP2}, which is positioned between the input signal V_{IN} and the gate of N_{DRIVE}, protects N_{DRIVE} from gate oxide breakdown by limiting the voltage across the gate-to-source (and gate-to-drain) junction of N_{DRIVE} when V_{IN} is at the logic HIGH state, at about V_{DDH} volts.

To ensure that the clipping FETs operate properly, the gate of each of the clipping FETs is biased at a voltage level which prevents each clipping FET from operating in saturation during those times when the FET is required to clip the voltage across a junction of the associated driving FET. For example, the gates of P_{CLIP1}, and P_{CLIP2} are tied to a voltage V_{LBIAS}, which resides at an intermediate value between V_{DDH}/2 and the ground reference voltage. Likewise, the gates of N_{CLIP1} and N_{CLIP2} have a voltage V_{HBIAS} forced thereupon at an intermediate value between V_{DDH} and V_{DDH}/2.

In the specific example of FIG. 5A, V_{HBIAS} and V_{LBIAS} are generated by way of an active voltage divider 200 formed from a set of four stacked PFETS P_{B1}, P_{B2}, P_{B3} and P_{B4} connected in series between V_{DDH} and ground. Each of the stacked PFETs is essentially in the OFF state, as the gate and source of each stacked PFET are connected together. As a result of the stacked configuration, V_{HBIAS} maintains a voltage of approximately 3V_{DDH}/4, while V_{LBIAS} resides at about V_{DDH}/4. Optionally, other circuits providing similar bias voltages may also be employed. In addition, low bias voltage V_{LBIAS} and high bias voltage V_{HBIAS} each may be coupled to the ground voltage reference via capacitors C_{H} and C_{L} to stabilize their voltage levels. These capacitors may be of substantial capacity (on the order of a microfarad, for example), especially if one such active voltage divider 200 is employed to service several enhanced driver circuits 100.

FIG. 5B displays an alternate active voltage divider 250 that uses four stacked NFETs N_{B1}, N_{B2}, N_{B3} and N_{B4}, with the gate of each NFET connected to the drain of that same NFET. The alternate active voltage divider 250 generates essentially the same values for V_{HBIAS} and V_{LBIAS} as those associated with the active voltage divider 200 of FIG. 5A.

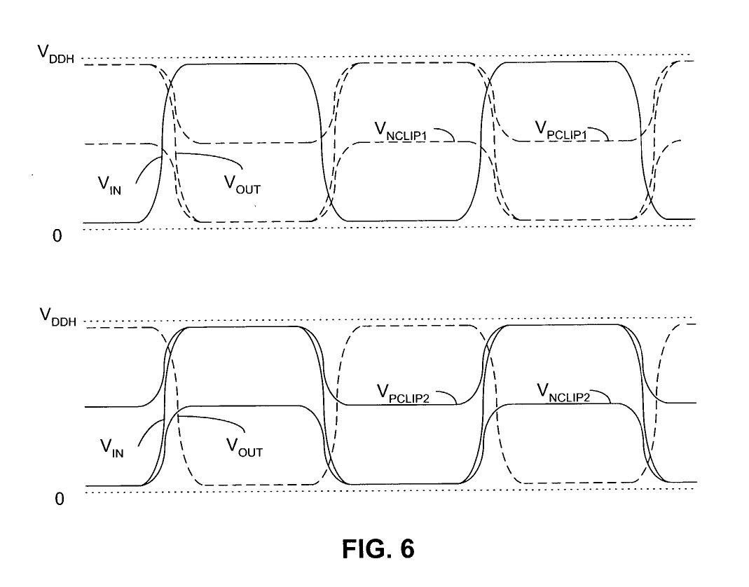

The effects of the clipping FETs, as biased by the high and low bias voltages, can be seen in the waveform diagrams of FIG. 6, while referencing the enhanced driver circuit 100 of FIG. 4. As V_{IN} proceeds from a logic LOW level to a logic HIGH of about V_{DDH} volts, the drain of N_{CLIP2} rises to that level. With V_{HBIAS} driving the gate of N_{CLIP2} to some voltage less than V_{DDH} to prevent saturation of N_{CLIP2} (3V_{DDH}/4, in this case), N_{CLIP2} develops a significant voltage across its drain-to-source junction, thereby allowing the voltage at the gate of N_{DRIVE} (indicated by the reference point V_{NCLIP2}) to rise to some level significantly less than V_{DDH} while still allowing the gate of N_{DRIVE} to be driven high enough to turn ON N_{DRIVE}. This action aids in pulling the drain of N_{DRIVE} and the source of N_{CLIP1} (indicated by the reference point V_{NCLIP1}) toward ground. With the gate of N_{CLIP1} biased at V_{HBIAS}, N_{CLIP1} is turned ON as well, pulling the output signal V_{OUT} approximately to the ground reference voltage.

As V_{OUT} is pulled LOW, thus pulling the source of P_{CLIP1} along with it, P_{CLIP1} tends toward the OFF state since the gate of P_{CLIP1} is held at the voltage level V_{LBIAS}. At the same time, with V_{IN} causing a HIGH logic level at the drain of P_{CLIP2}, and the gate of P_{CLIP2} being held at the low bias voltage V_{LBIAS}, P_{CLIP2} is essentially ON, thereby forcing the gate of P_{DRIVE} to a logic HIGH. Hence, P_{DRIVE} is turned OFF as well, causing the drain of P_{CLIP1} (indicated by the reference point V_{PCLIP1}) to reside at a voltage near the midpoint between V_{DDH} and ground, at which V_{OUT} is driven.

In the case that V_{IN} then is driven toward the ground reference voltage, the drain of P_{CLIP2} is pulled to ground as well. With the gate of P_{CLIP2} being held at V_{LBIAS} (in this case, V_{DDH}/4), P_{CLIP2} conducts at less than the saturation level, causing a significant voltage drop across the drain-to-source junction of P_{CLIP2}. As a result, the voltage at the gate of P_{DRIVE} (i.e., V_{PCLIP2}), drops to an intermediate voltage between V_{DDH} and ground which is low enough to turn ON P_{DRIVE}, which, in turn, causes the source of P_{DRIVE} and the drain of P_{CLIP1} (denoted by V_{PCLIP1}) to raise essentially to V_{DDH}. With the gate of P_{CLIP1}, being maintained at V_{LBIAS}, P_{CLIP1} is turned ON as well, causing V_{OUT} to rise essentially to V_{DDH}.

With V_{OUT} being pulled HIGH, along with the drain of N_{CLIP1}, N_{CLIP1} tends toward the OFF state because of the gate of N_{CLIP1} being held at V_{HBIAS}. At the same time, the LOW logic level of V_{IN} is forced upon the drain of N_{CLIP2}, thus causing N_{CLIP2} to be essentially turned ON, ensuring the source of N_{CLIP2} and the gate of N_{DRIVE} (i.e. V_{NCLIP2}) are brought down to essentially ground. N_{DRIVE} is thus essentially OFF, along with N_{CLIP1}. In that state, the drain of N_{DRIVE} and the source of N_{CLIP1} (indicated by V_{NCLIP1}) reside at an intermediate voltage between V_{DDH} and ground.

Thus, whether V_{IN} attains the logic HIGH level (at about V_{DDH} volts) or the logic LOW level (at about ground), none of the FETs of the enhanced driver circuit 100 sustain a voltage beyond which the FETs can safely handle. The maximum voltage across any FET will be in the neighborhood of V_{DDH}/2, depending on the physical characteristics of the FETs and the actual voltage levels of V_{HBIAS} and V_{LBIAS}. As a result, the FETs should be implemented using an IC technology that can handle voltages of about V_{DDH}/2 in order to prevent any damage or reliability problems due to overvoltage. For example, assuming IC technology of 2.5 volts is employed for the enhanced driver circuit 100, a V_{DDH} of 3.3 V, as well as input and output signal voltage swings between ground and 3.3 V, are handled effectively. However, power supply and signal voltage levels well in excess of 5 V would not be applicable to the use of 2.5 V IC technology.

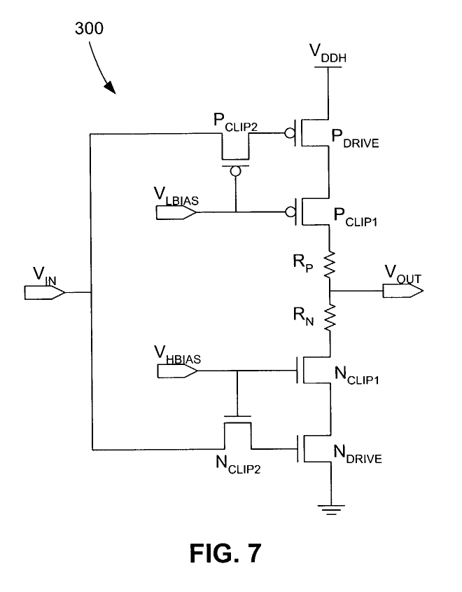

Other embodiments based upon the enhanced driver circuit 100 may also be employed in accordance with the present invention. For example, FIG. 7 shows a second enhanced driver circuit 300 comprising the FETs of the enhanced driver circuit 100 of FIG. 4 with a couple of additional linearizing resistors R_{P} and R_{N} connected in series with P_{CLIP1} and N_{CLIP1}. The junction of R_{P} and R_{N} form the signal output V_{OUT}. Other modifications of the enhanced driver circuit 100 may also be employed in accordance with the inventive concepts described herein.

Due to the additional FETs employed in enhanced driver circuit 100 over that required for the standard driver circuit 1, the total amount of capacitance of the enhanced driver circuit 100 that is charged and discharged when the input signal V_{IN} changes logic states causes the enhanced driver circuit 100 to operate more slowly in most cases than the standard driver circuit 1 of similar IC technology. As a result, embodiments of the present invention are particularly well-suited for applications that value small circuit footprint and design flexibility over the highest possible circuit switching speeds. For example, many system interface bus implementations, such as Peripheral Component Interconnect X (PCIX), a popular 64-bit computer bus architecture capable of running at bus speeds of up to 133 Megahertz (MHz), would benefit from employment of embodiments of the invention. Other systems requiring similar performance characteristics could particularly benefit the use of such driver circuits.

From the foregoing, the invention provides a simple digital signal driver circuit capable of driving high-voltage digital signals using comparatively low-voltage IC technology while eliminating the circuit damage and operational reliability problems exhibited by other driver circuits. Embodiments other than those shown above are also possible. As a result, the invention is not to be limited to the specific forms and arrangements of components so described and illustrated; the invention is limited only by the claims.

What is claimed is:

1. A digital signal driver circuit, comprising:
a driving n-channel FET coupled with a ground reference;
a first clipping n-channel FET configured to limit voltage across the drain-to-source junction of the driving n-channel FET;
a second clipping n-channel FET configured to limit voltage across the gate-to-source junction of the driving n-channel FET;
a driving p-channel FET coupled with a high voltage supply;
a first clipping p-channel FET configured to limit voltage across the drain-to-source junction of the driving p-channel FET;
a second clipping p-channel FET configured to limit voltage across the gate-to-source junction of the driving p-channel FET, the driving p-channel FET and the driving n-channel FET being coupled together to drive an output signal based on the logic state of an input signal.

2. The digital signal driver circuit of claim 1, wherein the first and second clipping n-channel FETs are controlled by a high bias voltage, and the first and second clipping p-channel FETs are controlled by a low bias voltage.

3. The digital signal driver circuit of claim 1, wherein the source of the first clipping n-channel FET is connected with the drain of the driving n-channel FET, the gate of the first clipping n-channel FET is driven by a high bias voltage, the drain of the first clipping p-channel FET is connected with the source of the driving p-channel FET, the gate of the first clipping n-channel FET is driven by a low bias voltage, and the source of the first clipping p-channel FET and the drain of the first clipping n-channel FET are connected together to produce the output signal.

4. The digital signal driver circuit of claim 3, further comprising:
an active voltage divider of four p-channel FETs connected serially between the high voltage supply and the ground reference, each gate of the four p-channel FETs being connected to the source of the same p-channel FET, the source of the p-channel FET that is connected to the high voltage supply being configured to generate the high bias voltage, the drain of the p-channel FET that is connected to the ground reference being configured to generate the low bias voltage.

5. The digital signal driver circuit of claim 3, further comprising:
an active voltage divider of four n-channel FETs connected serially between the high voltage supply and the ground reference, each gate of the four n-channel FETs being connected to the drain of the same n-channel FET, the source of the n-channel FET that is connected to the high voltage supply being configured to generate the high bias voltage, the drain of the n-channel FET that is connected to the ground reference being configured to generate the low bias voltage.

6. The digital signal driver circuit of claim 1, wherein the source of the second clipping n-channel FET is connected with the gate of the driving n-channel FET, the drain of the second clipping n-channel FET is driven by the input signal, the gate of the second clipping n-channel FET is driven by a high bias voltage, the drain of the second clipping p-channel FET is connected with the gate of the driving p-channel FET, the source of the second clipping p-channel FET is driven by the input signal, and the gate of the second clipping p-channel FET is driven by a low bias voltage.

7. The digital signal driver circuit of claim 6, further comprising:
an active voltage divider of four p-channel FETs connected serially between the high voltage supply and the ground reference, each gate of the four p-channel FETs being connected to the source of the same p-channel FET, the source of the p-channel FET that is connected to the high voltage supply being configured to generate the high bias voltage, the drain of the p-channel FET that is connected to the ground reference being configured to generate the low bias voltage.

8. The digital signal driver circuit of claim 6, further comprising:
an active voltage divider of four n-channel FETs connected serially between the high voltage supply and the ground reference, each gate of the four n-channel FETs being connected to the drain of the same n-channel FET, the source of the n-channel FET that is connected to the high voltage supply being configured to generate the high bias voltage, the drain of the n-channel FET that is connected to the ground reference being configured to generate the low bias voltage.

9. The digital signal driver circuit of claim 1, further comprising:
a first resistor that couples the driving p-channel FET with the output signal; and
a second resistor that couples the driving n-channel FET with the output signal.

10. An integrated circuit, comprising:
the digital signal driver circuit of claim 1.

11. A digital signal driver circuit, comprising:
a driving n-channel FET, the source of the driving n-channel FET being connected with a ground reference;
a first clipping n-channel FET, the source of the first clipping n-channel FET being connected with the drain of the driving n-channel FET, the gate of the first clipping n-channel FET being driven by a high bias voltage;
a second clipping n-channel FET, the source of the second clipping n-channel FET being connected with the gate of the driving n-channel FET, the drain of the second clipping n-channel FET being driven by an input signal, the gate of the second clipping n-channel FET being driven by the high bias voltage;
a driving p-channel FET, the drain of the driving p-channel FET being connected with a high voltage supply;
a first clipping p-channel FET, the drain of the first clipping p-channel FET being connected with the source of the driving p-channel FET, the gate of the first clipping n-channel FET being driven by a low bias voltage;
a second clipping p-channel FET, the drain of the second clipping p-channel FET being connected with the gate of the driving p-channel FET, the source of the second clipping p-channel FET being driven by the input signal, the gate of the second clipping p-channel FET being driven by the low bias voltage, the source of the first clipping p-channel FET and the drain of the first clipping n-channel FET being coupled together to produce an output signal.

12. The digital signal driver circuit of claim 11, further comprising:
a first resistor that connects the source of the first clipping p-channel FET with the output signal; and
a second resistor that connects the drain of the first clipping n-channel FET with the output signal.

13. The digital signal driver circuit of claim 11, further comprising:
an active voltage divider of four p-channel FETs connected serially between the high voltage supply and the ground reference, each gate of the four p-channel FETs being connected to the source of the same p-channel FET, the source of the p-channel FET that is connected to the high voltage supply being configured to generate the high bias voltage, the drain of the p-channel FET that is connected to the ground reference being configured to generate the low bias voltage.

14. The digital signal driver circuit of claim 11, further comprising:
an active voltage divider of four n-channel FETs connected serially between the high voltage supply and the ground reference, each gate of the four n-channel FETs being connected to the drain of the same n-channel FET, the source of the n-channel FET that is connected to the high voltage supply being configured to generate the high bias voltage, the drain of the n-channel FET that is connected to the ground reference being configured to generate the low bias voltage.

15. An integrated circuit, comprising:
the digital signal driver circuit of claim 11.
